(19) United States
(12) Patent Application Publication
(10) Pub. No.: US 2009/0108949 A1
(43) Pub. Date: Apr. 30, 2009

(54) TEMPERATURE COMPENSATION FOR CRYSTAL OSCILLATORS

(75) Inventors: Hongbo Yan, San Diego, CA (US); Daniel Fred Filipovic, Solana Beach, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 11/929,467

(22) Filed: Oct. 30, 2007

(51) Int. Cl. H03B 5/32

(52) U.S. Cl. 331/158

(57) ABSTRACT

Methods and apparatus for generating a temperature compensated frequency estimate for a crystal oscillator, wherein the temperatures of the crystal and oscillator are both accounted for. A crystal temperature measurement is used to generate a first frequency component. The difference between the oscillator temperature measurement and a second temperature is scaled, and used to generate a second frequency component. The first and second frequency components may be summed to produce a frequency estimate for the crystal oscillator. In an embodiment, the computations may be performed in the slope domain.

### TECHNICAL FIELD

The disclosure relates to frequency sources, and, more particularly, to temperature compensation for crystal oscillators.

### BACKGROUND

Crystal oscillators (XO) are used in circuit designs as frequency sources. In a typical crystal oscillator, a quartz crystal having a nominal resonant frequency is coupled to an oscillator circuit that generates a signal having a nominal output frequency. In practice, both the crystal's resonant frequency and the oscillator's output frequency may vary with such factors as temperature and aging. Typical temperature compensation schemes for crystal oscillators assume that the temperature of the crystal and the temperature of the oscillator are the same.

In some circuit designs, however, the temperature difference between the crystal and the oscillator may need to be taken into account. What is needed is a temperature compensation scheme for a crystal oscillator that can account for the temperature difference between the crystal and the oscillator.

### SUMMARY

An aspect of the present disclosure provides a method of generating a frequency estimate for a crystal oscillator, the method comprising receiving a measured oscillator temperature; receiving a measured crystal temperature; generating a first frequency component based on the measured crystal temperature; generating a second frequency component, the generating the second frequency component comprising computing a difference between the measured oscillator temperature and a second temperature term, the generating the second frequency component further comprising computing a function of said difference; and generating the frequency estimate based on the first and second frequency components.

Another aspect provides an apparatus for generating a frequency estimate for a crystal oscillator, the apparatus comprising a first frequency component generator for generating a first frequency component based on a measured crystal temperature; and a second frequency component generator for generating a second frequency component, the second frequency component comprising a function of a difference between a measured oscillator temperature and a second temperature term; the frequency estimate comprising the first and second frequency components.

Yet another aspect provides a computer program product for generating a frequency estimate for a crystal oscillator, the product comprising computer-readable medium comprising code for causing a computer to receive a measured oscillator temperature; code for causing a computer to receive a measured crystal temperature; code for causing a computer to generate a first frequency component based on the measured crystal temperature; code for causing a computer to generate a second frequency component, the second frequency component comprising a function of a difference between the measured oscillator temperature and a second temperature term; and code for causing a computer to generate the frequency estimate based on the first and second frequency components.

### BRIEF DESCRIPTION OF DRAWINGS

FIG. 1 depicts an embodiment of a crystal oscillator according to the present disclosure.

FIG. 1A depicts a typical dependence of oscillator frequency F_{osc} on temperature, wherein the crystal temperature Tₓ is assumed to be equal to the oscillator temperature T_{osc}, and both temperatures are referred to as T.

FIG. 2 shows an embodiment of a block 250 for implementing Equation 1.

FIG. 3 shows an embodiment of a block 350 for implementing Equation 1 in the slope (rate of change in time) domain as opposed to the frequency domain.

FIG. 3A shows an embodiment of a slope estimator.

FIG. 4 shows an embodiment wherein the frequency estimator output 410 computed by block 350 in FIG. 3 is further combined with another frequency estimate \hat{f} 420.

FIG. 5 depicts another embodiment wherein a frequency estimator output 510 is combined with an alternative frequency estimate \hat{f}.

FIG. 6 shows a typical function relating the crystal temperature T to the crystal frequency Fₓ.

FIG. 7 depicts an embodiment wherein the oscillator frequency estimate F′_{osc}(Tₓ, T_{osc}) is derived from the function Fₓ(Tₓ).

### DETAILED DESCRIPTION

Disclosed herein are temperature compensation techniques that account for the temperature difference between the crystal and the oscillator.

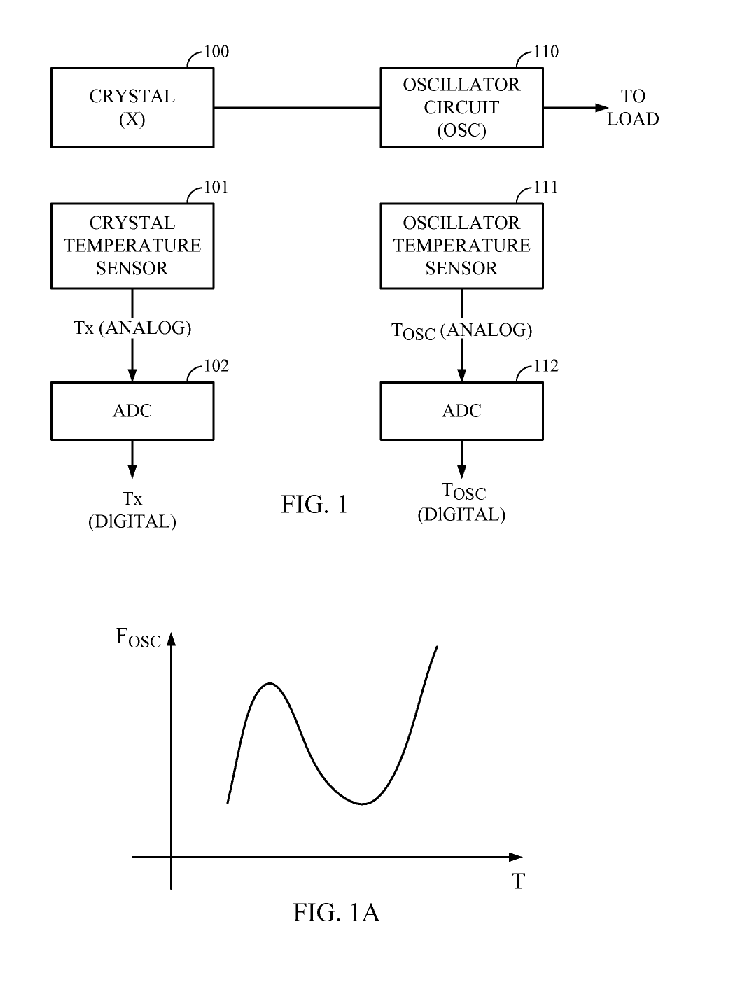

FIG. 1 depicts an embodiment of a crystal oscillator according to the present disclosure. A crystal (X) 100 is coupled to an oscillator circuit (OSC) 110. Crystal temperature sensor 101 senses the temperature of the crystal 100 and generates an analog signal Tₓ corresponding thereto. An analog-to-digital converter (ADC) 102 converts the analog measurement Tₓ (analog) to a digital measurement Tₓ (digital). Similarly, oscillator temperature sensor 111 senses the temperature of the oscillator 110 and generates an analog measurement T_{osc} (analog) corresponding thereto. An ADC 112 converts the analog measurement T_{osc} (analog) to a digital measurement T_{osc} (digital).

Note the ADC's 102, 112 may be omitted in some embodiments, for example, where the temperature measurements themselves are digital, or the computations described later herein are performed directly in the analog domain.

FIG. 1A depicts a typical dependence of oscillator frequency F_{osc} on temperature, wherein the crystal temperature Tₓ is assumed to be equal to the oscillator temperature T_{osc}, and both temperatures are referred to as T. In this specification and in the claims, this function may be referred to as “F_{osc}(T)” or “the first F-T function.” F_{osc}(T) for a given crystal oscillator may be derived empirically through measurements. F_{osc}(T) may be pre-programmed into a memory, or interpolated from discrete samples stored in a look-up table, or be made available via offline or online calibration, or via any other mechanism.

In an embodiment, a look-up table stores discrete samples of F_{osc}(T). Values of F_{osc}(T) not stored in the look-up table may be interpolated from the stored samples.

In an alternative embodiment, the function F_{osc}(T) may be generated by a polynomial as follows (Equation 1):

F_{osc}(T)=c₃(T−T₀)³+c₂(T−T₀)²+c₁(T−T₀)+c₀;

wherein T₀ is a suitably chosen reference temperature, and c₃, c₂, c₁, and c₀ are the polynomial coefficients. According to this embodiment, F_{osc}(T) may be specified by simply storing T₀ and the coefficients c₃, c₂, c₁, and c₀ in memory.

To account for a difference between the measured temperatures Tₓ and T_{osc}, the oscillator frequency F′_{osc}(T_{osc}, Tₓ) can be estimated as follows (Equation 2):

F′_{osc}(T_{osc}, Tₓ)=F_{osc}(Tₓ)+c_{L}(T_{osc}−Tₓ).

The first term F_{osc}(Tₓ) on the right side of Equation 2 is simply the result of inputting the crystal temperature Tₓ into the function F_{osc}(T).

The second term on the right side of Equation 2, c_{L}(T_{osc}−Tₓ), is the product of a constant term c_{L} and the difference between the oscillator and crystal temperatures, T_{osc}−Tₓ. In an embodiment, c_{L} can be empirically determined by 1) measuring the oscillator frequency F′_{osc}(T_{osc}, Tₓ) corresponding to temperatures T_{osc}, Tₓ, and 2) determining the term c_{L} required to “fit” the frequency point F_{osc}(Tₓ) to the measured F′_{osc}(T_{osc}, Tₓ). In an embodiment, the empirical determination may be averaged over multiple temperature-frequency points to improve the estimate of c_{L}. c_{L} can be preprogrammed into memory, or obtained via offline or online calibration, or via any other mechanism.

Note in general, the second term on the right side of Equation 2 may be replaced by a function of the difference (T_{osc}−Tₓ) as follows (Equation 2a):

F′_{osc}(T_{osc}, Tₓ)=F_{osc}(Tₓ)+f(T_{osc}−Tₓ);

where f (T_{osc}−Tₓ) is any function of the difference (T_{osc}−Tₓ). Such a function can be linear, e.g., c_{L} (T_{osc}−Tₓ) as given in Equation 2. Alternatively, the function may be a polynomial expressed by a₀+a₁(T_{osc}−Tₓ)+a₂(T_{osc}−Tₓ)²+a₃(T_{osc}−Tₓ)³+ . . . In an embodiment, the polynomial coefficients a₁, a₁, a₂, a₃, etc., may be determined by empirical curve-fitting, as described above for the term c_{L} in Equation 2. According to the present disclosure, any function of the temperature difference (T_{osc}−Tₓ) may be employed to compute the function F′_{osc}(T_{osc}, Tₓ) and the disclosure should not be limited to the embodiments explicitly described. The implementation of a polynomial or any general function of the difference (T_{osc}−Tₓ) will be clear to one of ordinary skill in the art in light of the disclosures herein, and will not be explicitly described.

Note in this specification and in the claims, the term “first frequency component” may be understood to encompass the term F_{osc}(Tₓ) in Equations 2 and 2a, and the term “second frequency component” may be understood to encompass the term c_{L} (T_{osc}−Tₓ) in Equation 2, or any other general function f(T_{osc}−Tₓ) of the difference (T_{osc}−Tₓ), as given in Equation 2a.

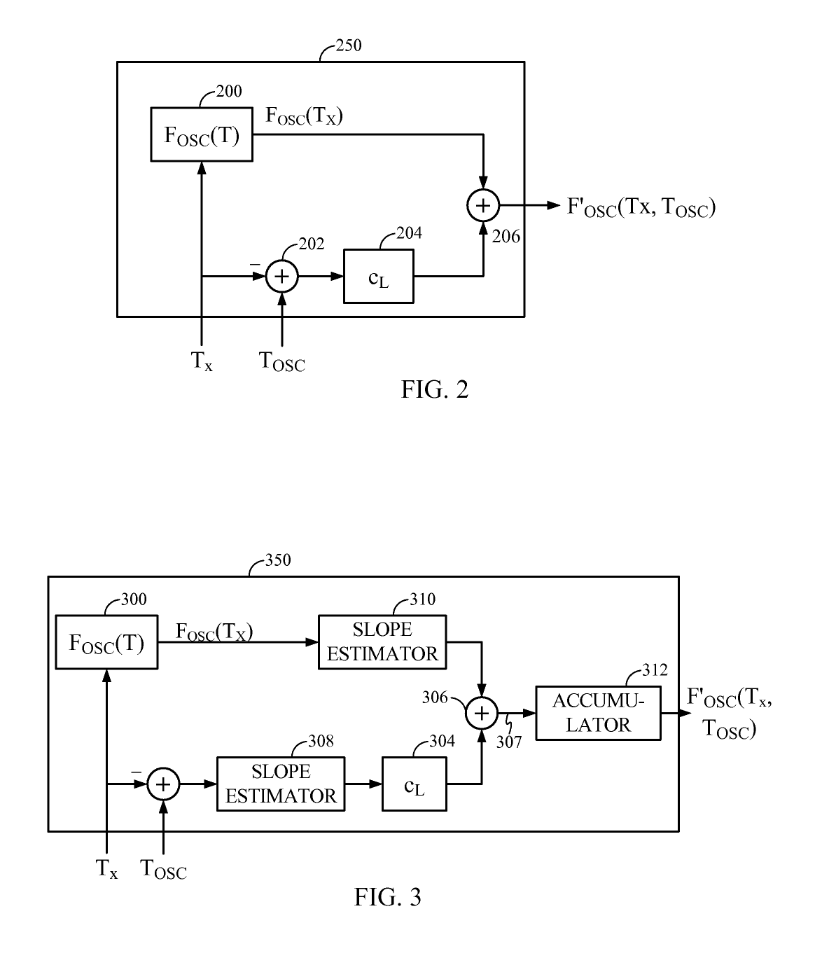

FIG. 2 shows an embodiment of a block 250 for implementing Equation 2. Note block 250 is described for illustrative purposes only, and is not meant to limit the scope of the present disclosure to any particular implementation of Equation 2. In block 250, block 200 may implement the function F_{osc}(T) such as depicted in FIG. 1A.

In FIG. 2, the crystal temperature Tₓ is input to the function F_{osc}(T) 200, which outputs a corresponding frequency F_{osc}(Tₓ), or the first frequency component. Crystal temperature Tₓ is also subtracted from oscillator temperature T_{osc} by adder 202, and the output of the adder is multiplied by a multiplier c_{L} 204 to produce the second frequency component. The first frequency component is added to the second frequency component by adder 206 to produce the frequency estimate F′_{osc} (Tₓ, T_{osc}) which is output by the block 250.

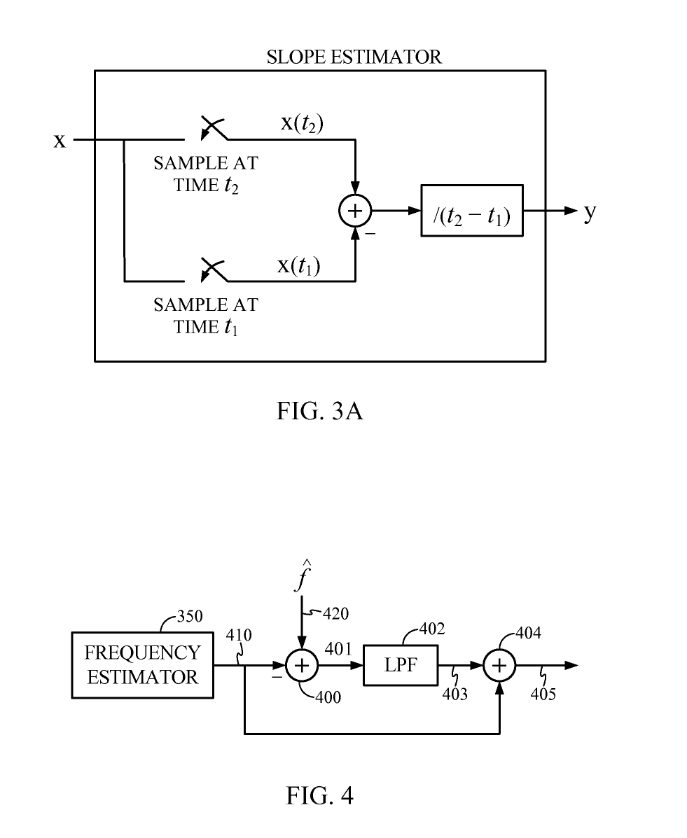

FIG. 3 shows an embodiment of a block 350 for implementing Equation 1 in the slope domain, as opposed to the frequency domain implementation depicted in FIG. 2. In this specification and in the claims, the “frequency domain” refers to frequency values sampled in time, while the “slope domain” refers to the rate of change (over time) of frequency values sampled in time. Elements in block 350 prefixed with a “3” correspond to similarly numbered elements in block 250 prefixed with a “2.” Block 350 includes two slope estimators 308, 310 and an accumulator 312, for which corresponding elements in block 250 are not present.

In an embodiment, each of the slope estimators 308, 310 performs the following function on an input x to produce an output y:

$$y = \frac{x ( {t}_{2} ) - x ( {t}_{1} )}{{t}_{2} - {t}_{1}} ;$$

wherein t₁ and t₂ represent two separate instants in time, and x(t₂) and x(t₁) represent the values of x sampled at times t₂ and t₁, respectively. FIG. 3A shows an embodiment of a slope estimator. Note FIG. 3A is shown for illustrative purposes only, and is not meant to limit the implementation of a slope estimator to the embodiment shown.

Referring back to FIG. 3, the embodiment shown uses slope estimator 310 to estimate the slope of the term F_{osc}(Tₓ), and slope estimator 308 to estimate the slope of the term (Tₓ−T_{osc}). The slope estimators update the estimated slope over successive, discrete instants of time. By using the slope estimators, subsequent calculations may be performed in the slope domain rather than in the frequency domain.

Accumulator 312 is provided after the adder 306. The accumulator may continuously (or in discrete time) accumulate the values calculated in the slope domain to obtain the frequency values in the frequency domain. For example, in FIG. 3, assume that the output 307 of adder 306 is a slope s₁₂ corresponding to a rate of change of a value over a time interval [t1, t2]. Then, if the accumulator 312 is a discrete-time accumulator, its output at a time t2+Δ may be expressed as follows (Equation 2b):

Accum_output[t2+Δ]=Accum_output[t2]+s₁₂·Δ;

where Δ is the discrete-time accumulator's accumulation interval. In an embodiment, the value of the slope used by the accumulator in Equation 2b may be updated as soon as a new value of slope is available. In an embodiment, the time interval (t2−t1) over which a slope is calculated need not equal the discrete-time accumulator interval Δ used by the accumulator. Δ may be more than, less than, or equal to (t2−t1).

Performing computations in the slope domain, and then accumulating the computed slopes back to the frequency domain, may be advantageous in certain embodiments as large discontinuous changes in the estimated frequency value are avoided. Slope domain calculations also cancel out any constant offsets present over time, e.g., DC offsets present in the Analog-to-Digital Converter (ADC) used for converting the analog measurements of Tₓ and T_{osc} to digital measurements.

Note the slope estimators may be simple difference estimators if the incremental change in time (t2−t1) is kept constant throughout the signal path. Note however that the incremental change in time (t2−t1) need not be kept constant among the slope estimators.

In alternative embodiments, each instance of a slope estimator may be followed or preceded by a low-pass filter (not shown). A low-pass filter may be added to each instance of a slope estimator described or depicted in this specification.

Note the slope estimators need not be positioned as shown in FIG. 3. The conversion from frequency domain to slope domain, and subsequently from slope domain to frequency domain, may generally be done anywhere along the signal path, and the conversions to and from the slope domain may be performed multiple times. Such modifications will be clear to those of ordinary skill in the art.

In alternative embodiments, the slope estimators described may be replaced by or supplemented with any prediction mechanism for estimating future frequency values based on past and/or present frequency-temperature samples. For example, certain assumptions may be made about the maximum rate of change of frequency and temperature vs. time, and combinations of bandlimited functions such as sinc functions may be used to predict future frequency samples. In another embodiment, Kalman filtering may be applied to obtain future frequency samples based on past and present samples. Such modifications will be clear to one of ordinary skill in the art in light of the present disclosure, and are contemplated to be within the scope of the present disclosure.

FIG. 4 shows an embodiment wherein the frequency estimator output 410 computed by block 350 in FIG. 3 is further combined with another frequency estimate \hat{f} 420. In an embodiment, the frequency estimate \hat{f} 420 may be an estimate derived independently of the frequency estimator 350, e.g., an estimate derived from an automatic frequency control (AFC) circuit, or other source such as digital hardware, software program code, or firmware. In an embodiment, \hat{f} 420 may be derived from an AFC module within a CDMA receiver. Information from the frequency estimate \hat{f} 420 may be utilized to improve the accuracy of the frequency estimator output 410. In FIG. 4, the difference 401 between \hat{f} 420 and the frequency estimator output 410 is filtered by low-pass filter (LPF) 402. The low-pass filter output 403 is then added back to the frequency estimator output 410 by adder 404 to generate a new estimate 405.

Note the embodiment depicted in FIG. 4 may also be modified to perform all or a portion of the calculations in the slope domain, as described previously with respect to FIG. 3. In an embodiment, this may be done by placing additional slope estimators and accumulators in the signal path shown in FIG. 4 as appropriate, and/or removing slope estimators and accumulators from the internal signal paths of the frequency estimator 350. Such modifications will be clear to those of ordinary skill in the art, and are contemplated to be within the scope of the present disclosure.

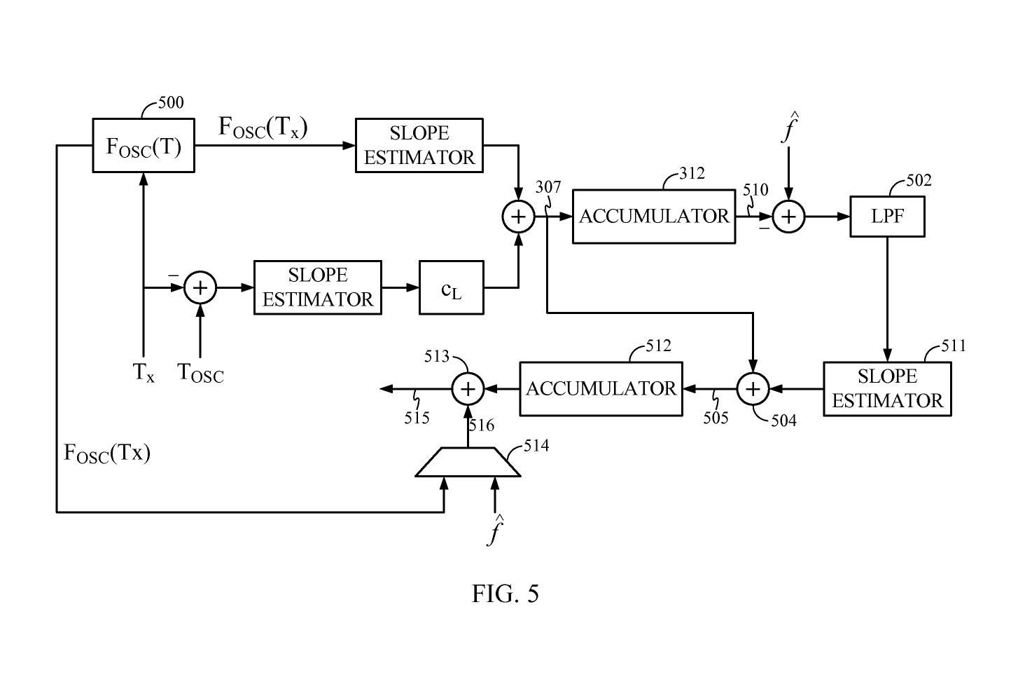

FIG. 5 depicts an alternative embodiment wherein a frequency estimator output 510 is combined with another frequency estimate \hat{f}. In FIG. 5, the output of the low-pass filter 502 is first converted to the slope domain by slope estimator 511, then added by adder 504 to the frequency slope estimate 307. The accumulator 512 converts the output 505 of the adder 504 from the slope domain back to the frequency domain.

In an embodiment, if accumulators 312 and 512 are initialized to an initial frequency value at the start of the slope domain calculations, then the outputs of accumulators 312 and 512 each represent an absolute temperature-dependent frequency that is the sum of the initial frequency value and an accumulated difference component resulting from the slope domain calculations. In this embodiment, the outputs of the accumulators 312 and 512 may each be directly supplied to other components as the temperature-compensated estimate of absolute oscillator frequency. The accumulators 312 and 512 may be initialized to, for example, the value of F′osc(Tₓ, T_{osc}) according to Equation (2). Any other frequency initialization value may also be used, such as F_{osc}(Tₓ) or the alternative frequency estimate \hat{f}.

In an alternative embodiment, if accumulator 512 is instead initialized to zero at the start of the slope domain calculations, then the output of accumulator 512 merely represents an accumulated difference component resulting from the slope domain calculations. In this case, to derive the absolute oscillator frequency estimate, adder 513 is provided to add the accumulated difference component back to an initial frequency estimate 516.

In the embodiment shown, the initial frequency estimate is selected by a mux 514 from either the alternative frequency estimate \hat{f} or from the output of the F(T) estimator 500. In an embodiment, the frequency estimate \hat{f} is selected over the output of the F(T) estimator whenever \hat{f} is available. In another embodiment (not shown), the value of F′_{osc}(Tₓ, T_{osc}) according to Equation (2) may be one of the values selectable by the mux. Note the initial frequency estimate 516 need not be determined as shown or described, but can be chosen from any suitable initial frequency estimate.

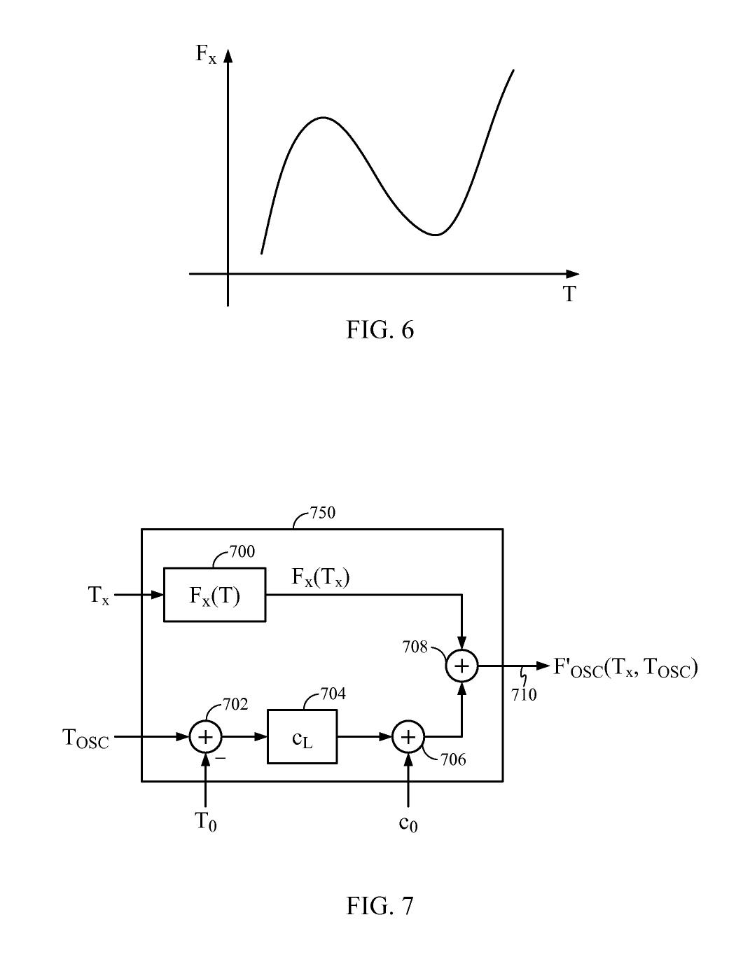

Note the techniques disclosed herein may also be applied to embodiments based on a function Fₓ(T) characterizing the dependence of a crystal's frequency Fₓ on crystal temperature T. FIG. 6 shows a typical instance of the function Fₓ(T). In this specification and in the claims, this function may be referred to as “Fₓ(T)” or “the second F-T function.” Like the function F_{osc}(T), the function Fₓ(T) can be stored as entries in a look-up table, or computed as a polynomial function, or computed according to any other implementation.

In an embodiment utilizing the function Fₓ(T), the oscillator frequency is estimated as follows (Equation 3):

F′_{osc}(T_{osc}, Tₓ)=Fₓ(Tₓ)+c_{L}(T_{osc}−T₀)+c₀;

wherein T₀ is a fixed reference temperature, Tₓ is the actual measured crystal temperature, and c₀ is a fixed term related to the capacitance loading the oscillator.

FIG. 7 depicts an embodiment wherein the oscillator frequency estimate F′_{osc}(Tₓ, T_{osc}) is derived from the function Fₓ(T) as computed according to Equation 3. In the upper signal path, the measured crystal temperature Tₓ is input to a function Fₓ(T) 700 to produce Fₓ(Tₓ). In the lower signal path, a reference temperature T₀ is subtracted from the oscillator temperature T_{osc} using adder 702. The output of adder 702 is multiplied by a linear constant c_{L} in block 704. The output of block 704 is added to a constant term c₀ by adder 706. The output of the adder 706 is added to Fₓ(Tₓ) by adder 708 to produce a frequency estimate 710.

One of ordinary skill in the art will recognize that the techniques described elsewhere in this disclosure may also be applied to the embodiment depicted in FIG. 7. For example, the calculations may be done in the slope domain and converted back to the frequency domain. The estimate 710 may be similarly combined with an alternative estimate \hat{f} as described earlier with reference to FIG. 4.

Note in general, the second and third terms of the right side of Equation 3 may be replaced by a function of the difference (T_{osc}−T₀) as follows (Equation 3a):

F′_{osc}(T_{osc}, Tₓ)=Fₓ(Tₓ)+f(T_{osc}−T₀);

where f (T_{osc}−T₀) is any function of the difference (T_{osc}−T₀). In a preferred embodiment, the function can be linear, e.g., c_{L} (T_{osc}−T₀)+c₀ as given in Equation 3. According to other embodiments, any function may be employed, e.g., a polynomial expressed by b₀+b₁(T_{osc}−T₀)+b₂(T_{osc}−T₀)²+b₃(T_{osc}−T₀)³+ . . . In an embodiment, the coefficients b₀, b₁, b₂, b₃, etc., may be derived through empirical curve-fitting, as described previously for coefficients a₀, a₁, a₂, a₃, etc. According to the present disclosure, any function of the temperature difference (T_{osc}−T₀) may be employed to compute the function F′_{osc}(T_{osc}, Tₓ) and the disclosure should not be limited to the embodiments explicitly described.

Note in this specification and in the claims, the term “first frequency component” may also be understood to encompass the term Fₓ(Tₓ) in Equations 3 and 3a, and the term “second frequency component” may also be understood to encompass the term c_{L} (T_{osc}−T₀)+c₀ in Equation 3, or any other general function f(T_{osc}−T₀) of the difference (T_{osc}−T₀), as given in Equation 3a.

Based on the teachings described herein, it should be apparent that an aspect disclosed herein may be implemented independently of any other aspects and that two or more of these aspects may be combined in various ways. The techniques described herein may be implemented in hardware, software, firmware, or any combination thereof. If implemented in hardware, the techniques may be realized using digital hardware, analog hardware or a combination thereof. If implemented in software, the techniques may be realized at least in part by a computer-program product that includes a computer readable medium on which one or more instructions or code is stored.

By way of example, and not limitation, such computer-readable media can comprise RAM, such as synchronous dynamic random access memory (SDRAM), read-only memory (ROM), non-volatile random access memory (NVRAM), ROM, electrically erasable programmable read-only memory (EEPROM), erasable programmable read-only memory (EPROM), FLASH memory, CD-ROM or other optical disk storage, magnetic disk storage or other magnetic storage devices, or any other tangible medium that can be used to carry or store desired program code in the form of instructions or data structures and that can be accessed by a computer.

The instructions or code associated with a computer-readable medium of the computer program product may be executed by a computer, e.g., by one or more processors, such as one or more digital signal processors (DSPs), general purpose microprocessors, ASICs, FPGAs, or other equivalent integrated or discrete logic circuitry.

A number of aspects and examples have been described. However, various modifications to these examples are possible, and the principles presented herein may be applied to other aspects as well. These and other aspects are within the scope of the following claims.

1. A method of generating a frequency estimate for a crystal oscillator, the method comprising:
receiving a measured oscillator temperature;
receiving a measured crystal temperature;
generating a first frequency component based on the measured crystal temperature;
generating a second frequency component, the generating the second frequency component comprising computing a difference between the measured oscillator temperature and a second temperature term, the generating the second frequency component further comprising computing a function of said difference; and
generating the frequency estimate, the generating the frequency estimate comprising adding the first and second frequency components.

2. The method of claim 1, the computing a function of said difference comprising scaling the difference by a scalar.

3. The method of claim 2, the second temperature term being the measured crystal temperature.

4. The method of claim 3, the generating the first frequency component comprising inputting the measured crystal temperature to a first F-T function.

5. The method of claim 4, the first F-T function comprising a polynomial expansion of the oscillator temperature, the coefficients of said polynomial expansion stored in a memory.

6. The method of claim 3, further comprising:
estimating the slope of the first frequency component; and
estimating the slope of the second frequency component;
the generating the frequency estimate based on the first and second frequency components comprising summing the estimated slopes of the first and second frequency components, and accumulating the sum of the estimated slopes.

7. The method of claim 6, further comprising summing the accumulated sum of the estimated slopes with an initial frequency, the initial frequency being the second frequency estimate, or the first frequency component, or a first frequency estimate, the first frequency estimate being the sum of the first and second frequency components.

8. The method of claim 7, further comprising selecting the second frequency estimate over the first frequency component when the second frequency estimate is available.

9. The method of claim 3, the generating the frequency estimate based on the first and second frequency components comprising:
adding the first and second frequency components to produce a first frequency estimate;
computing the difference between the first frequency estimate and a second frequency estimate;
filtering the computed difference between the first and second frequency estimates; and
summing the filtered computed difference with the first frequency estimate to produce an adjusted first frequency estimate.

10. The method of claim 9, the adjusted first frequency estimate being the frequency estimate for the crystal oscillator.

11. The method of claim 10, the second frequency estimate being an automatic-frequency control estimate.

12. The method of claim 3, further comprising:
estimating the slope of the first frequency component; and
estimating the slope of the second frequency component; the generating the frequency estimate based on the first and second frequency components comprising:
summing the estimated slopes of the first and second frequency components to produce a first frequency slope estimate;
accumulating the first frequency slope estimate;
computing the difference between the accumulated first frequency slope estimate and a second frequency estimate;
filtering the computed difference between the accumulated first frequency slope estimate and the second frequency estimate;
estimating the slope of the filtered computed difference;
summing the estimated slope of the filtered computed difference with the first frequency slope estimate; and
accumulating the sum of the estimated slope of the filtered computed difference with the first frequency slope estimate.

13. The method of claim 12, further comprising:
summing the accumulated sum with an initial frequency, the initial frequency being the second frequency estimate, or the first frequency component, or a first frequency estimate, the first frequency estimate being the sum of the first and second frequency components.

14. The method of claim 2, the second temperature term being a fixed reference temperature.

15. The method of claim 14, the generating a first frequency component comprising inputting the measured crystal temperature to a second F-T function.

16. The method of claim 15, further comprising:
estimating the slope of the first frequency component; and
estimating the slope of the second frequency component;
the generating the frequency estimate based on the first and second frequency components comprising summing the estimated slopes of the first and second frequency components, and accumulating the sum of the estimated slopes.

17. An apparatus for generating a frequency estimate for a crystal oscillator, the apparatus comprising:
a first frequency component generator for generating a first frequency component based on a measured crystal temperature; and
a second frequency component generator for generating a second frequency component, the second frequency component comprising a function of a difference between a measured oscillator temperature and a second temperature term, the frequency estimate comprising the sum of the first and second frequency components.

18. The apparatus of claim 17, the second temperature term being the measured crystal temperature.

19. The apparatus of claim 18, the frequency estimate comprising the sum of the first and second frequency components.

20. The apparatus of claim 18, further comprising:
a first slope estimator for estimating the slope of the first frequency component;
a second slope estimator for estimating the slope of the second frequency component; and
an accumulator for accumulating the sum of the estimates of the slopes of the first and second frequency components, the output of the accumulator being a first frequency estimate.

21. The apparatus of claim 18, further comprising:
a difference generator for computing the difference between a first frequency estimate and a second frequency estimate, the first frequency estimate being the sum of the first and second frequency components;
a filter for filtering the difference;
an adder for summing the filtered difference with the first frequency estimate.

22. A computer program product for generating a frequency estimate for a crystal oscillator, the product comprising:
computer-readable medium comprising:
code for causing a computer to receive a measured oscillator temperature;
code for causing a computer to receive a measured crystal temperature;
code for causing a computer to generate a first frequency component based on the measured crystal temperature;
code for causing a computer to generate a second frequency component, the second frequency component comprising a function of a difference between the measured oscillator temperature and a second temperature term; and
code for causing a computer to generate the frequency estimate comprising the sum of the first and second frequency components.

23. The computer program product of claim 22, the second temperature term being the measured crystal temperature.

24. The computer program product of claim 23, the code for causing a computer to generate the frequency estimate based on the first and second frequency components comprising code for causing a computer to add the first and second frequency components.

25. The computer program product of claim 23, the computer-readable medium further comprising:
code for causing a computer to estimate the slope of the first frequency component;
code for causing a computer to estimate the slope of the second frequency component;
code for causing a computer to sum the estimated slopes of the first and second frequency components; and
code for causing a computer to accumulate the sum of the estimated slopes.
